(19) United States
(12) Patent Application Publication
(10) Pub. No.: US 2007/0145443 A1
(43) Pub. Date: Jun. 28, 2007

(54) CMOS Image Sensor and Method of Manufacturing the Same

(76) Inventor: Keun Hyuk Lim, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/611,205

(22) Filed: Dec. 15, 2006

(30) Foreign Application Priority Data
Dec. 28, 2005 (KR) 10-2005-0132682

(51) Int. Cl. H01L 31/113

(52) U.S. Cl. 257/292

(57) ABSTRACT

A CMOS image sensor is provided. The CMOS image sensor includes: a photodiode region formed in an active region of a substrate; a transistor formed on a transistor region of the active region of the substrate; a low-concentration diffusion region formed on the photodiode region while being spaced apart from a device isolation region of the substrate; a high-concentration diffusion region formed in the low-concentration diffusion region; and a floating diffusion region formed in a drain region of the transistor.

### RELATED APPLICATION(S)

This application claims the benefit under 35 USC §119(e) of Korean Patent Application No. 10-2005-0132682 filed Dec. 28, 2005, which is incorporated herein by reference in its entirety.

### FIELD OF THE INVENTION

The present invention relates to a CMOS image sensor and a method of manufacturing the same.

### BACKGROUND OF THE INVENTION

Image sensors are semiconductor devices for converting optical images into electric signals, and are generally classified as charge coupled devices (CCDs) or CMOS image sensors.

In a CCD, a plurality of photodiodes (PDs) for converting light into electric signals are arranged in the form of a matrix.

In addition, the CCD includes a plurality of vertical charge coupled devices (VCCI)s) vertically arranged in the matrix between photodiodes so as to transmit electric charges in the vertical direction when the electric charges are generated from each photodiode; a plurality of horizontal charge coupled devices (HCCDs) for transmitting the electric charges that have been transmitted from the VCCDs in the horizontal direction; and a sense amplifier for outputting electric signals by sensing the electric charges being transmitted in the horizontal direction.

However, such a CCD has various disadvantages, such as a complicated drive mode, high power consumption, and so forth. Also, the CDD requires multi-step photo processes, so the manufacturing process for the CCD is complicated.

Further, since it is difficult to integrate control circuits, signal processing circuits, A/D converters and the like on a CCD chip, the miniaturization of products is hard to accomplish.

Recently, CMOS image sensors have been spotlighted as the next-generation image sensor for overcoming these disadvantages of the CCDs.

The CMOS image sensors are devices employing a switching scheme. In particular, MOS transistors are formed on a semiconductor substrate using a CMOS technology, and control circuits, signal processing circuits and the like are used as peripheral circuits, so that outputs of respective unit pixels can be sequentially detected by the MOS transistors.

That is, in CMOS image sensors, a photo diode and a MOS transistor are formed in each unit pixel so that electric signals of the respective unit pixels can be sequentially detected in a switching scheme, thereby implementing images.

Since CMOS manufacturing technology is used in fabricating the CMOS image sensors, the CMOS image sensor can have a reduced power consumption and a reduced number of photo process steps, thereby simplifying the manufacturing process as compared with the CCD.

Further, since control circuits, signal processing circuits, A/D converters and the like can be integrated onto an image sensor chip, the CMOS image sensors have an advantage in that the miniaturization of products is easy to accomplish.

Accordingly, the CMOS image sensors have been widely used in various applications such as digital still cameras and digital video cameras.

The CMOS image sensor is classified as 3T-type, 4T-type, 5T-type or the like depending on the number of transistors formed in each unit pixel. The 3T-type CMOS image sensor includes one photodiode and three transistors, and the 4T-type CMOS image sensor includes one photodiode and four transistors.

A layout for a unit pixel of the 4T-type CMOS image sensor is described below with reference to FIGS. 1 and 2.

FIG. 1 is an equivalent circuit of a 4T-type CMOS image sensor according to the related art, and FIG. 2 is a layout showing a unit pixel of the 4T-type CMOS image sensor according to the related art.

As shown in FIG. 1, the unit pixel 100 of the CMOS image sensor includes a photodiode (PD) 10, serving as a photoelectric conversion portion, and four transistors.

Here, the four transistors are transfer, reset, drive and selection transistors 20, 30, 40 and 50, respectively. Further, a load transistor 60 is connected electrically to an output terminal OUT of each unit pixel 100.

Reference FD denotes a floating diffusion region, and references Tx, Rx, and Sx denote gate signals of the transfer, reset, and selection transistors 20, 30, and 50, respectively. Referring to FIG. 2, in the unit pixel of the 4T-type CMOS image sensor according to the related art, an active region 13 is defined having a wide portion and a narrow portion. One photodiode is formed on the portion having a broad width in the active region 13, and the four gate electrodes 23, 33, 43 and 53 for the four transistors are formed overlapping the narrow portion of the active region 13.

That is, transfer, reset, drive and selection transistors 20, 30, 40 and 50 are formed by the first, second, third and fourth gate electrodes 23, 33, 43 and 53, respectively.

The source/drain region of each of the transistors are formed by implanting impurity ions into the active region around but not directly below each of the gate electrodes 23, 33, 43 and 53.

FIGS. 3A to 3C are sectional views taken along line I-I′ in FIG. 2 for illustrating a process of manufacturing a CMOS image sensor according to the related art.

As shown in FIG. 3A, a first conductive type low-concentration epitaxial layer 62 is formed on a first conductive type semiconductor substrate 61 by performing an epitaxial process.

Subsequently, active and device isolation regions are defined in the semiconductor substrate 61, and device isolation films 63 are formed in the device isolation region using an STI process.

An insulating film 64 and a conductive layer (e.g., a high-concentration polycrystalline silicon layer) are sequentially deposited on the entire surface of the epitaxial layer 62 having the device isolation films 63, and portions of the conductive layer and the gate insulating film 64 are removed to form a gate electrode 65.

Referring to FIG. 3B, a first photoresist is coated on the entire surface of the semiconductor substrate 61 and patterned through an exposure and development process to expose photodiode regions. Often the photodiode regions correspond to blue, green and red color wavelengths, respectively.

Then, a second conductive type low-concentration diffusion region 67 is formed in the photodiode region by implanting second conductive type impurity ions at low-concentration into the epitaxial layer 62 using the patterned first photoresist as a mask.

After the first photoresist is completely removed, an insulating film is deposited on the entire surface of the semiconductor substrate 61, and spacers 68 are then formed on both side surfaces of the gate electrode 65 by performing an etch-back process. Thereafter, a second photoresist is coated on the entire surface of the semiconductor substrate 61 and patterned through an exposure and development process such that the photo diode regions are covered and the source/drain regions of the respective transistors are exposed.

A second conductive type floating diffusion region 70 is formed by implanting second conductive type impurity ions at high-concentration into the exposed source/drain regions using the patterned second photoresist as a mask.

Referring to FIG. 3C, after the second photoresist is removed, a third photoresist is coated on the entire surface of the semiconductor substrate 61, and the third photoresist is patterned through an exposure and development process such that the photodiode regions are exposed. Then, a first conductive type diffusion region 72 is formed by implanting first conductive type impurity ions into the photodiode regions having the second conductive type low-concentration diffusion region 67 by using the patterned third photoresist as a mask. Thereafter, the third photoresist is removed, and the respective impurity diffusion regions are diffused by performing a heat-treatment process.

The second conductive type low-concentration diffusion region 67, in which electrons are gathered in the photodiode regions, is formed to have a depth similar to that of the device isolation film 63 and a broad width. Therefore, diffusion region 67 is formed in the entire region between the gate electrode 65 and the device isolation film 63.

However, because the diffusion region 67 has a broad width, the light receiving characteristic of a photodiode corresponding to red, or long wavelengths, may vary depending on the depletion region 69. In addition, due to the second conductive type low-concentration diffusion region 67 being directly adjacent to the device isolation film 63, a defect may occur between the second conductive type low-concentration diffusion region 67 and the device isolation film 63, thereby generating a dark current.

Further, there is a problem in that the second conductive type low-concentration diffusion region 67 increases a crosstalk phenomenon with adjacent pixels.

### BRIEF SUMMARY

It is, therefore, an object of the present invention to provide a CMOS image sensor for enhancing characteristics of photodiodes and a method of manufacturing the CMOS image sensor.

It is another object of the present invention to provide a CMOS image sensor capable of preventing the occurrence of a dark current and reducing cross-talk phenomenon with neighboring pixels, and a method of manufacturing the CMOS image sensor.

In accordance with a preferred embodiment of the present invention, there is provided a CMOS image sensor incorporating: a semiconductor substrate having an active region and a device isolation region for a unit pixel; a photodiode region formed in the active region; a transistor formed on the active region adjacent the photodiode region; a low-concentration diffusion region formed in the photodiode region while being spaced apart from the device isolation region, and a high-concentration diffusion region formed on the low-concentration diffusion region; and a floating diffusion region formed in a drain region of the transistor.

In accordance with another preferred embodiment of the present invention, there is provided a CMOS image sensor incorporating: a semiconductor substrate having an active region and a device isolation region; a photodiode region formed in the active region; a transistor formed on the active region adjacent the photodiode region; a second conductive type low-concentration diffusion region formed on the photodiode region while being spaced apart from the device isolation region; a first conductive type high-concentration diffusion region formed on the second conductive type low-concentration diffusion region; and a second conductive type floating diffusion region formed in a drain region of the transistor.

In accordance with a further preferred embodiment of the present invention, there is provided a method of manufacturing a CMOS image sensor, including: forming device isolation films in a semiconductor substrate for defining an active region and a device isolation region; forming a gate insulating film and a gate electrode on the active region; forming a second conductive type low-concentration diffusion region spaced apart from the device isolation film in the photodiode region of the active region; forming spacers at both side surfaces of the gate electrode; forming a second conductive type floating diffusion region in a drain region of the gate electrode; and forming a first conductive type diffusion region on the second conductive type low-concentration diffusion region in the photodiode region.

### BRIEF DESCRIPTION OF THE DRAWINGS

FIG. 1 is an equivalent circuit of a 4T-type CMOS image sensor according to the related art;

FIG. 2 is a layout showing a unit pixel of the 4T-type CMOS image sensor according to the related art;

FIGS. 3A to 3C are sectional views illustrating a process of manufacturing a CMOS image sensor according to the related art; and

FIGS. 4A to 4C are sectional views illustrating a process of manufacturing a CMOS image sensor according to an embodiment of the present invention.

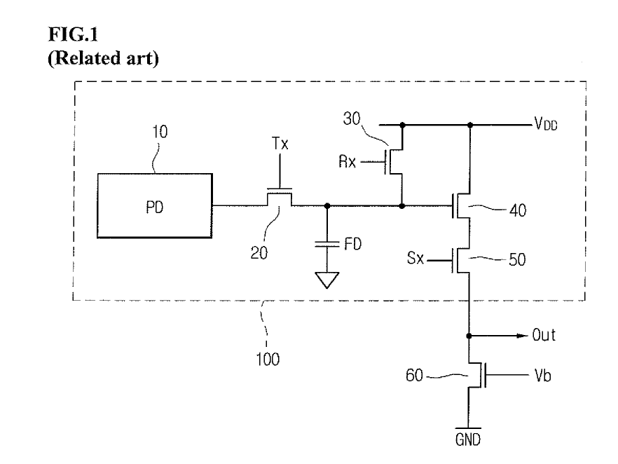

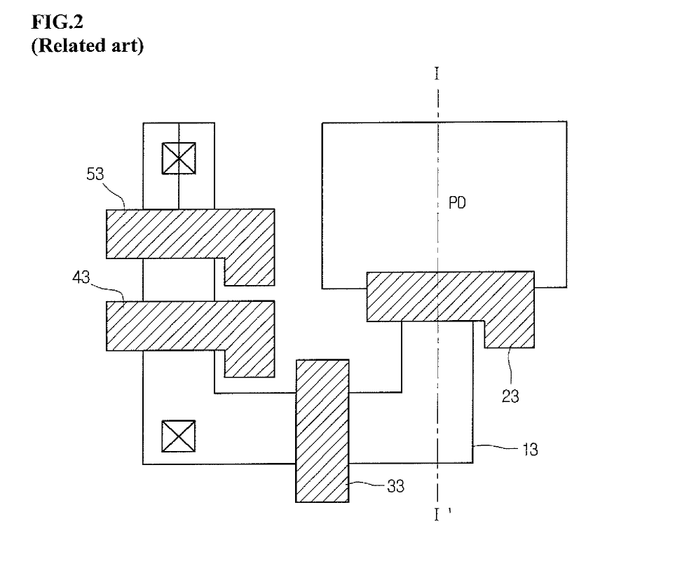

### DETAILED DESCRIPTION OF THE INVENTION

Hereinafter, a CMOS image sensor and a method of manufacturing the same according to embodiments of the present invention will be described with reference to the accompanying drawings.

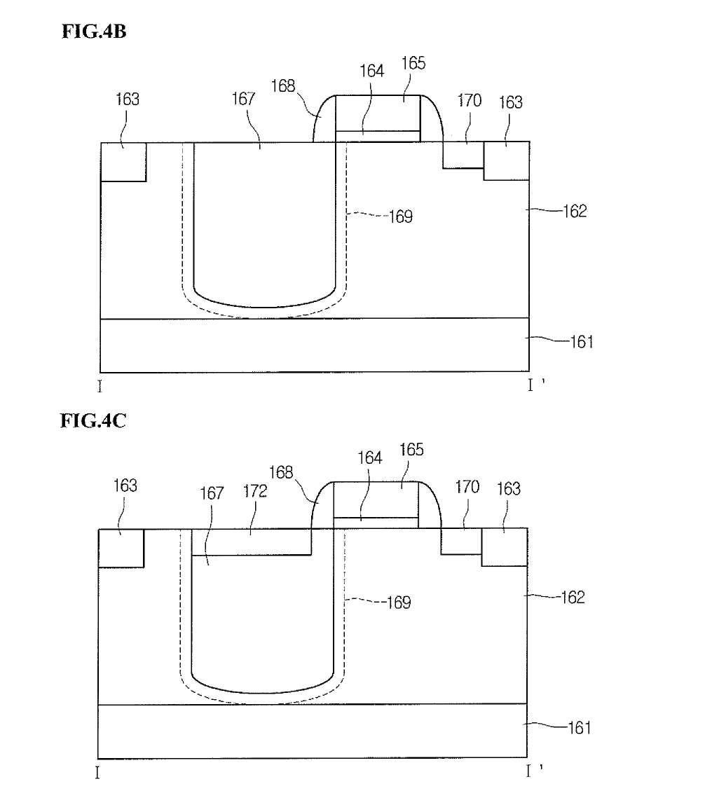

FIGS. 4A to 4C are sectional views illustrating a process of manufacturing a CMOS image sensor according to an embodiment of the present invention.

Referring to FIG. 4A, an epitaxial layer 162 is formed on a semiconductor substrate 161 of a first conductive type by an epitaxial process. The epitaxial layer 162 can be of a low-concentration first conductive type.

Active and device isolation regions can be defined in the semiconductor substrate 161. In an embodiment, device isolation films 163 can be formed in the device isolation region using an STI process. In a specific embodiment, the device isolation film 163 can be formed to a depth of 0.4 to 0.5 μm.

A method of forming the device isolation films 163 is described below.

First, a pad oxide, a pad nitride and a TEOS (Tetra Ethyl Ortho Silicate) oxide can be sequentially formed on a semiconductor substrate. Then, a photoresist can be formed on the TEOS oxide. Subsequently, the photoresist can be patterned by being exposed and developed using a mask defining the active and device isolation regions such that the photoresist in the device isolation region is removed.

Then, the pad oxide, the pad nitride and the TEOS oxide in the device isolation region are selectively removed using the patterned photoresist as a mask.

Subsequently, trenches can be formed by etching the semiconductor substrate in the device isolation region using the patterned pad oxide, pad nitride and TEOS oxide as a mask.

Thereafter, the trenches can be filled with a dielectric material, thereby forming the device isolation films 163 within the trenches. Subsequently, the pad oxide, the pad nitride and the TEOS oxide can be removed.

Referring again to FIG. 4A, an insulating film for a gate insulating film 164 and a conductive layer can be sequentially deposited on the entire surface of the epitaxial layer 162 having the device isolation films 163 formed therein. In an embodiment, the conductive layer can be a polysilicon layer.

The insulating film may be formed through a thermal oxidation process or a CVD technique.

Then, the conductive layer and the insulating film can be selectively removed to form a gate electrode 165 on the substrate with a gate insulating film 164 therebetween.

Referring to FIG. 4B, a first photoresist can be coated on the entire surface of the semiconductor substrate 161 having the gate electrode 165 and the gate insulating film 164, and the first photoresist can be selectively patterned through an exposure and development process to expose a portion of the photodiode region. In the preferred embodiment, the portion of the photodiode region adjacent to the device isolation film 163 should not be exposed.

Then, a second conductive type low-concentration diffusion region 167 can be formed in the exposed photodiode region by implanting second conductive type impurity ions at low-concentration into the epitaxial layer 162 using the patterned first photoresist as a mask. In one embodiment, a phosphorous ion may be used as an n-type impurity ion for the second conductive type impurity ion. In a specific embodiment, phosphorous ions can be implanted at a dose of 1×10¹¹ to 1×10¹³ cm².

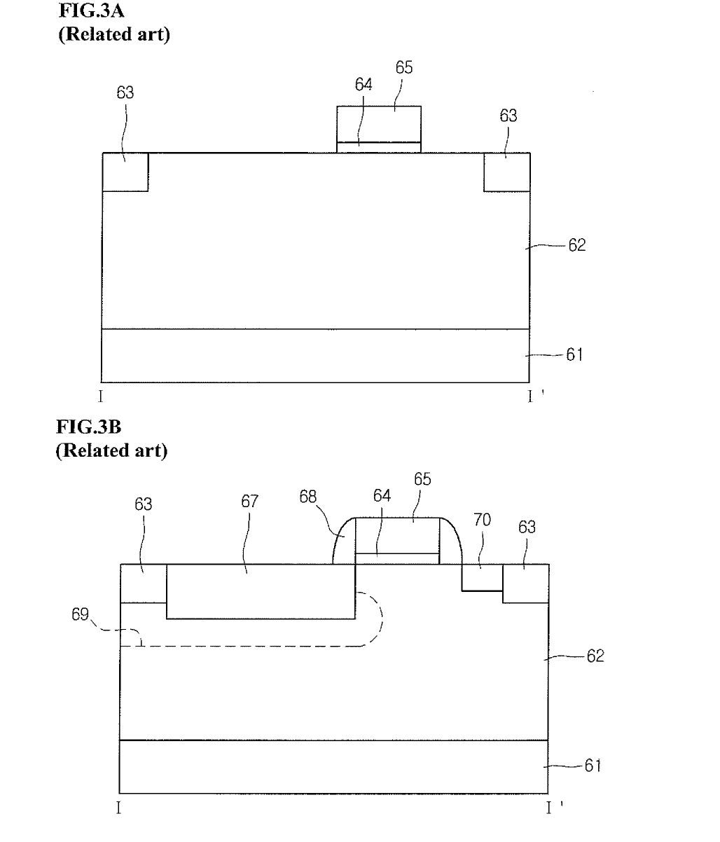

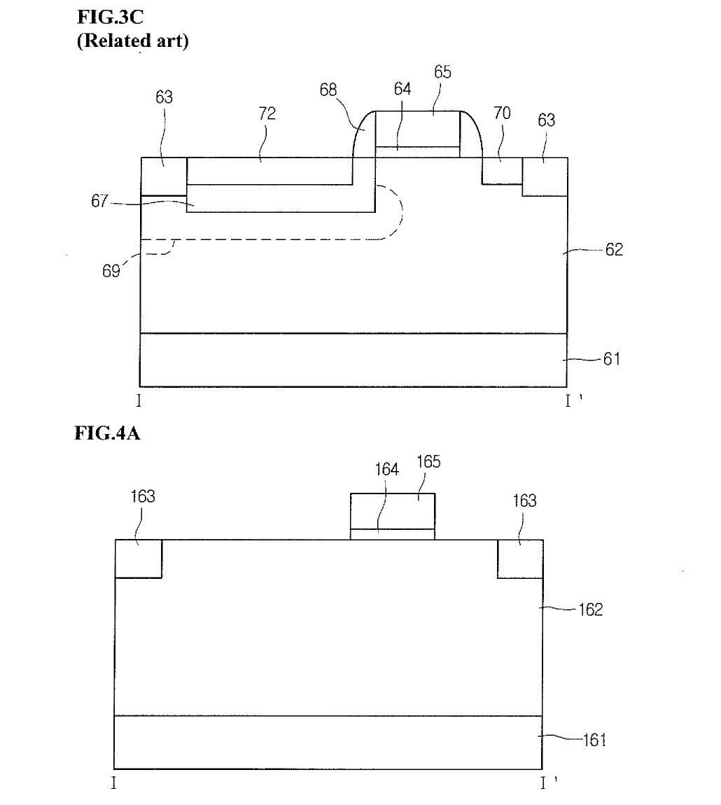

The second conductive type low-concentration diffusion region 167 can be formed to have a narrow width and a deep depth as compared with the related art second conductive type low-concentration diffusion region 67 shown in FIG. 3B. That is, in a specific embodiment, the width of the second conductive type low-concentration diffusion region 167 can be about 0.8 to 1.0 μm, and the depth can be about 1.6 to 2 μm. In an embodiment, to form the diffusion region 167 to a depth of 1.6 to 2 μm from the surface of the photodiode region, the second conductive type impurity ions can be implanted at an implantation energy of 3 MkeV. In a further embodiment, the second conductive type impurity ions can be implanted into the substrate while gradually reducing the implantation energy.

Because the second conductive type low-concentration diffusion region 167 can be formed to be deep as described above, a depletion region 169 is also formed deeply. Therefore, the light receiving characteristic of a photodiode corresponding to red, or long wavelengths, can be enhanced.

Accordingly, with a space between the device isolation film 163 and the diffusion region 167, the device isolation film 163 and the second conductive type low-concentration diffusion region 167 are not directly adjacent to each other. Therefore, a dark current can be reduced and a crosstalk phenomenon with adjacent pixels can be decreased.

Referring again to FIG. 4B, after the first photoresist is removed, an insulating film can be formed on the entire surface of the semiconductor substrate 161 including the second conductive type low-concentration diffusion region 167. Then, spacers 168 can be formed on both side surfaces of the gate electrode 165 by performing an etch-back process of the insulating film.

Thereafter, a second photoresist can be coated on the entire surface of the semiconductor substrate 161 and patterned through an exposure and development process to cover the photodiode regions and expose the source/drain regions. FIG. 4B illustrates a floating diffusion region of the source/drain regions.

A second conductive type floating diffusion region 170 can be formed by implanting second conductive type impurity ions at high-concentration into the exposed source/drain region using the patterned second photoresist as a mask.

Referring to FIG. 4C, after the second photoresist is removed, a third photoresist can be coated on the entire surface of the semiconductor substrate 161 and patterned through an exposure and development process to expose a portion of the photodiode regions. In one embodiment, the same mask can be used for both the first photoresist pattern and the third photoresist pattern. A first conductive type high-concentration diffusion region 172 can be formed on the second conductive type low-concentration diffusion region 167 by implanting first conductive type impurity ions at high-concentration into the epitaxial layer 162 having the second conductive type low-concentration diffusion region 167 using the patterned third photoresist as a mask.

After the third photoresist is removed, the impurity diffusion regions can be diffused by performing a heat-treatment process on the semiconductor substrate 161.

Thereafter, although subsequent processes are not shown in the figures, the image sensor can be completed by forming metal wirings having multiple interlayer insulating films, color filter layers, and micro-lenses.

According to embodiments of the present invention, there is an advantage in that a low-concentration diffusion region can be formed deeply so that the light receiving characteristic of red wavelengths (i.e. long wavelengths) in a photodiode can be enhanced.

Further, according to embodiments of the present invention, there is an advantage in that, if the width of a low-concentration diffusion region is formed narrowly, the low-concentration diffusion region is not adjacent to a device isolation film so that a dark current can be reduced and a crosstalk phenomenon with an adjacent pixel can be decreased.

I claim:

1. A CMOS image sensor comprising;
a semiconductor substrate having an active region and a device isolation region for a unit pixel;
a photodiode region formed in the active region;
a transistor formed in the active region adjacent the photodiode region;
a low-concentration diffusion region formed on the photodiode region while being spaced apart from the device isolation region;
a high-concentration diffusion region formed on the low-concentration diffusion region; and
a floating diffusion region formed in a drain region of the transistor.

2. The CMOS image sensor of claim 1, wherein the transistor comprises a gate insulating film, a gate electrode, and spacers.

3. The CMOS image sensor of claim 1, wherein the low-concentration diffusion region has a width of 0.8 μm to 1.0 μm and a depth of 1.6 μm to 2.0 μm.

4. A CMOS image sensor comprising.
a semiconductor substrate having an active region and a device isolation region;
a photodiode region formed in the active region;
a transistor formed on the active region adjacent the photodiode region;
a second conductive type low-concentration diffusion region formed on the photodiode region while being spaced apart from the device isolation region;
a first conductive type high-concentration diffusion region formed on the second conductive type low-concentration diffusion region; and
a second conductive type floating diffusion region formed in a drain region of the transistor.

5. The CMOS image sensor of claim 4, further comprising a first conductive type low-concentration epitaxial layer formed in the active region.

6. The CMOS image sensor of claim 4, wherein the second conductive type low-concentration diffusion region is formed by implanting n-type impurity ions.

7. The CMOS image sensor of claim 6, wherein the n-type impurity ion is phosphorous.

8. The CMOS image sensor of claim 6, wherein the n-type impurity ions are implanted at a dose of 1×10¹¹ to 1×10¹³/cm².

9. The CMOS image sensor of claim 4, wherein the second conductive type low-concentration diffusion region is formed to a depth of 1.6 μm to 2 μm from a surface of the photodiode region.

10. The CMOS image sensor of claim 4, wherein the second conductive type low-concentration diffusion region has a width of 0.8 μm to 1.0 μm.

11. The CMOS image sensor of claim 4, wherein the transistor comprises a gate insulating film, a gate electrode, and spacers.

12. A method of manufacturing a CMOS image sensor, comprising:
forming a device isolation film on a semiconductor substrate to define an active region and a device isolation region in the semiconductor substrate;
forming a gate insulating film and a gate electrode on the active region;
forming a second conductive type low-concentration diffusion region on a photodiode region of the active region spaced apart from the device isolation film;
forming spacers at both side surfaces of the gate electrode;
forming a second conductive type floating diffusion region in a drain region of the gate electrode; and
forming a first conductive type diffusion region on the second conductive type low-concentration diffusion region in the photodiode region.

13. The method of claim 12, wherein forming a second conductive type low-concentration diffusion region comprises:
selectively patterning a photoresist to expose the photodiode region except a portion of the photodiode region adjacent to the device isolation film; and
implanting second conductive type impurity ions into the exposed photodiode region.

14. The method of claim 12, further comprising forming a first conductive type low-concentration epitaxial layer on the semiconductor substrate.

15. The method of claim 12, wherein forming the second conductive type low-concentration diffusion region comprises implanting n-type impurity ions.

16. The method of claim 15, wherein the n-type impurity ion is phosphorous.

17. The method of claim 15, wherein the n-type impurity ions are implanted at a dose of 1×10¹¹ to 1×10¹¹³/cm².

18. The method of claim 15, wherein implanting the n-type impurity ions comprises implanting n-type impurity ions while gradually reducing an implantation energy.

19. The method of claim 12, wherein the second conductive type low-concentration diffusion region is formed to a depth of 1.6 μm to 2 μm from a surface of the photodiode region.

20. The method of claim 12, wherein the second conductive type low-concentration diffusion regions has a width of 0.8 μm to 1.0 μm.
